(19) United States
(12) Patent Application Publication
(10) Pub. No.: US 2026/0339218 A1
(43) Pub. Date: Oct. 29, 2026

(54) METHOD FOR EXTRACTING FEATURE SIZE OF LITHOGRAPHIC STRUCTURE AND RELATED APPARATUS

(71) Applicant: INSTITUTE OF MICROELECTRONICS, CHINESE ACADEMY OF SCIENCES, Beijing (CN)

(72) Inventors: Zitao Wei, Beijing (CN); Libin Zhang, Beijing (CN); Yayi Wei, Beijing (CN); Ge Liu, Beijing (CN); Yajuan Su, Beijing (CN)

(21) Appl. No.: 19/372,205

(22) Filed: Oct. 28, 2025

(30) Foreign Application Priority Data
Apr. 29, 2025 (CN) 202510555949.6

(51) Int. Cl. G03F 7/00

(52) U.S. Cl. CPC G03F 7/70625; G03F 7/705; G03F 7/70558; G03F 7/70655

(57) ABSTRACT

A method for extracting feature size of a lithographic structure and related apparatus is provided, applied to the field of semiconductors. An electron microscope image of lithographic structure and simulated structure constructed based on the lithographic structure are acquired. Based on the simulated structure and a preset duty cycle set of the simulated structure, for each duty cycle, a first grey level curve of first-type secondary electron image and second grey level curve of second-type secondary electron image are simulated, and the first and second grey level curves are superimposed based on a preset ratio to obtain a simulated grey level curve. A target duty cycle is determined based on fitting degrees between simulated grey level curves and an actual grey level curve of the electron microscope image, thereby calculating a target feature size of the lithographic structure based on the target duty cycle.

### CROSS-REFERENCE TO RELATED APPLICATIONS

The present application claims priority to Chinese Patent Application No. 202510555949.6, titled “METHOD FOR EXTRACTING FEATURE SIZE OF LITHOGRAPHIC STRUCTURE AND RELATED APPARATUS,” filed on Apr. 29, 2025 with the China National Intellectual Property Administration, which is incorporated herein by reference in its entirety.

### FIELD

The present disclosure relates to the technical field of semiconductors, and in particular to a method for extracting a feature size of a lithographic structure and related apparatus.

### BACKGROUND

With the continuous scaling down of process nodes in semiconductor manufacturing, a feature size of a lithographic structure becomes increasingly smaller, making it more challenging to extract the feature size such as a width of a photoresist line structure.

Currently, an edge of the lithographic structure is typically detected based on a variation of an average grey level of an electron microscope image of the lithographic structure, and the feature size of the lithographic structure is then calculated based on extracted edge information. However, for a lithographic structure formed over a metal layer, a brightness contrast at the edge of the lithographic structure in the electron microscope image may be distorted, resulting in difficulty for accurately extracting the feature size of the lithographic structure.

Accordingly, how to extract a feature size of a lithographic structure formed over a metal layer more accurately becomes an issue to be addressed.

### SUMMARY

Based on the issue described above, a method for extracting a feature size of a lithographic structure and related apparatus are provided according to the present disclosure, to more accurately extract the feature size of the lithographic structure formed over on a metal layer.

The following technical solutions are provided according to embodiments of the present disclosure.

In a first aspect, a method for extracting a feature size of a lithographic structure is provided according to the present disclosure. The method includes:
acquiring an electron microscope image of the lithographic structure, and a simulated structure constructed based on the lithographic structure, where the lithographic structure is formed over a metal layer;
performing simulation, for each duty cycle in a preset duty cycle set, to obtain a first grey level curve of a first-type secondary electron image and a second grey level curve of a second-type secondary electron image that are corresponding to the duty cycle based on the simulated structure and the preset duty cycle set of the simulated structure, where the first-type secondary electron refers to a secondary electron excited by an interaction between an incident electron beam and a surface of the lithographic structure, and the second-type secondary electron refers to a secondary electron generated by secondary excitation of a backscattered electron;
superimposing, for each duty cycle in the preset duty cycle set, the first grey level curve and the second grey level curve based on a preset ratio to obtain a simulated grey level curve corresponding to the duty cycle;
determining a target duty cycle based on a fitting degree between the simulated grey level curve and an actual grey level curve of the electron microscope image; and
calculating a target feature size of the lithographic structure based on the target duty cycle.

In an embodiment, after the calculating a target feature size of the lithographic structure based on the target duty cycle, the method further includes:
extracting a measured feature size of the lithographic structure based on a scanning grey level curve corresponding to the electron microscope image;
calculating a bias value corresponding to a lithographic material used in the lithographic structure based on a difference between the target feature size and the measured feature size; and
calculating a target feature size of a to-be-measured structure made of a same lithographic material as the lithographic structure, based on the bias value corresponding to the lithographic material used in the lithographic structure

In an embodiment, the extracting a measured feature size of the lithographic structure based on a scanning grey level curve corresponding to the electron microscope image includes:
determining x-coordinates of at least two preset grey level percentage points between a first peak point and a second peak point adjacent to the first peak point, based on y-coordinates of the first peak point and the second peak point and a y-coordinate of a valley point between the first peak point and the second peak point on a scanning grey level curve corresponding to the electron microscope image; and
extracting the measured feature size of the lithographic structure based on a difference between x-coordinates of points having a same grey level percentage, where the points having the same grey level percentage are among the at least two preset grey level percentage points between the first peak point and the second peak point.

In an embodiment, the calculating a target feature size of a to-be-measured structure made of a same lithographic material as the lithographic structure, based on the bias value corresponding to the lithographic material used in the lithographic structure includes:
acquiring an electron microscope image of a to-be-measured structure made of the same lithographic material as the lithographic structure;
extracting a measured feature size of the to-be-measured structure based on the electron microscope image of the to-be-measured structure; and
correcting the measured feature size of the to-be-measured structure based on the bias value corresponding to the lithographic material used in the lithographic structure to obtain the target feature size of the to-be-measured structure.

In an embodiment, after the acquiring an electron microscope image of the lithographic structure, the method further includes:
calculating an actual grey level curve of a target region in the electron microscope image, where the target region includes at least one pitch of the lithographic structure, and where
the performing simulation, for each duty cycle in a preset duty cycle set, to obtain a first grey level curve of a first-type secondary electron image and a second grey level curve of a second-type secondary electron image that are corresponding to the duty cycle based on the simulated structure and the preset duty cycle set of the simulated structure includes:
performing simulation, for each duty cycle in the preset duty cycle set, to obtain a first grey level curve and a second grey level curve corresponding to the duty cycle based on the simulated structure and the preset duty cycle set of the simulated structure, where the first grey level curve is for a region of first-type secondary electron image that corresponds to the target region and the second grey level curve is for a region of the second-type secondary electron image that corresponds to the target region.

In an embodiment, after the calculating an actual grey level curve of a target region in the electron microscope image, the method further includes:
performing interpolation on the actual grey level curve, to cause the number of data points on the actual grey level curve to be consistent with the number of data points on the simulated grey level curve.

In an embodiment, the calculating a target feature size of the lithographic structure based on the target duty cycle includes:
calculating the target feature size of the lithographic structure based on the target duty cycle and a designed pitch of the lithographic structure.

In a second aspect, an apparatus for extracting a feature size of a lithographic structure is provided according to an embodiment of the present disclosure. The apparatus includes: an acquisition module, a simulation module, a superimposing module, a fitting module, and a first calculation module, where
the acquisition module is configured to acquire an electron microscope image of the lithographic structure, and a simulated structure constructed based on the lithographic structure, where the lithographic structure is formed over a metal layer;
the simulation module is configured to perform simulation, for each duty cycle in a preset duty cycle set, to obtain a first grey level curve of a first-type secondary electron image and a second grey level curve of a second-type secondary electron image that are corresponding to the duty cycle based on the simulated structure and the preset duty cycle set of the simulated structure, where the first-type secondary electron refers to a secondary electron excited by an interaction between an incident electron beam and a surface of the lithographic structure, and the second-type secondary electron refers to a secondary electron generated by secondary excitation of a backscattered electron;
the superimposing module is configured to superimpose, for each duty cycle in the preset duty cycle set, the first grey level curve and the second grey level curve based on a preset ratio to obtain a simulated grey level curve corresponding to the duty cycle;
the fitting module is configured to determine a target duty cycle based on a fitting degree between the simulated grey level curve and an actual grey level curve of the electron microscope image; and
the first calculation module is configured to calculate a target feature size of the lithographic structure based on the target duty cycle.

In a third aspect, a device for extracting a feature size of a lithographic structure is provided according to an embodiment of the present disclosure, where the device includes a memory and a processor;
the memory is configured to store program codes and transmit the program codes to a processor; and
the processor is configured to, based on the program codes, execute the method for extracting the feature size of the lithographic structure according to any embodiment in the first aspect.

In a fourth aspect, a computer-readable storage medium is provided according to an embodiment of the present disclosure. Computer programs are stored in the computer-readable storage medium, when the computer programs are executed by the device for extracting the feature size of the lithographic structure, the device for extracting the feature size of the lithographic structure performs the method for extracting the feature size of the lithographic structure according to any embodiment in the first aspect.

Beneficial effects provided by the present disclosure compared with conventional technologies are described below.

A method for extracting a feature size of a lithographic structure is provided according to the embodiment of the present disclosure. In the method, an electron microscope image of a lithographic structure and a simulated structure constructed based on the lithographic structure are acquired, where the lithographic structure is formed over a metal layer. Based on the simulated structure and a preset duty cycle set of the simulated structure, for each duty cycle in the preset duty cycle set, a first grey level curve of a first-type secondary electron image corresponding to the duty cycle, and a second grey level curve of a second-type secondary electron image corresponding to the duty cycle are simulated. The first-type secondary electron refers to a secondary electron excited by an interaction between an incident electron beam and a surface of the lithographic structure, and the second-type secondary electron refers to a secondary electron generated by secondary excitation from a backscattered electron. Further, for each duty cycle in the preset duty cycle set, the first grey level curve and the second grey level curve are superimposed based on a preset ratio to obtain a simulated grey level curve corresponding to the duty cycle. The target duty cycle is determined based on the fitting degrees between the simulated grey level curves and the actual grey level curve of the electron microscope image. Therefore, a target feature size of the lithographic structure is calculated based on the target duty cycle.

Accordingly, an image library for multiple duty cycles is constructed through simulation. A signal from the first-type secondary electrons reflecting the surface morphology and a signal from the second-type secondary electrons related to materials are combined to obtain a simulated grey level curve. Further, fitting is performed between the simulated grey level curve and the actual grey level curve to determine the target duty cycle, thereby obtaining the feature size of the lithographic structure through calculation. The method for extracting the feature size does not require direct measurement of the feature size of the lithographic structure based on the electron microscope image, and can effectively overcome high backscattering interference from the metal layer, thereby enabling more accurate extraction of the feature size of the lithographic structure formed over the metal layer.

### BRIEF DESCRIPTION OF THE DRAWINGS

For more clearly illustrating the technical solutions in the embodiments of the present disclosure or in the conventional technology, drawings referred to describe the embodiments or the conventional technology will be briefly described hereinafter. Apparently, the drawings in the following description are related to some embodiments of the present disclosure, and for those skilled in the art, other drawings may be obtained based on these drawings without any creative efforts.

FIG. 1 is a flowchart illustrating a method for extracting a feature size of a lithographic structure according to an embodiment of the present disclosure;

FIG. 2 is a schematic structural diagram illustrating a to-be-measured sample according to an embodiment of the present disclosure;

FIG. 3 is a schematic diagram illustrating simulated first-type secondary electron images respectively corresponding to different duty cycles according to an embodiment of the present disclosure;

FIG. 4 is a schematic diagram illustrating simulated second-type secondary electron images respectively corresponding to different duty cycles according to an embodiment of the present disclosure;

FIG. 5 is a schematic diagram illustrating a first grey level curve and a second grey level curve according to an embodiment of the present disclosure;

FIG. 6 is a schematic diagram illustrating an electron microscope image of a target region according to an embodiment of the present disclosure;

FIG. 7 is a schematic diagram illustrating an actual grey level curve of a target region according to an embodiment of the present disclosure;

FIG. 8 is a schematic diagram illustrating grey level curve fitting effect according to an embodiment of the present disclosure;

FIG. 9 is a flowchart illustrating a method for extracting a feature size of a to-be-measured structure based on bias value calibration according to an embodiment of the present disclosure;

FIG. 10 is a schematic diagram illustrating positions of preset grey level percentage points according to an embodiment of the present disclosure;

FIG. 11 is a schematic diagram illustrating an apparatus for extracting a feature size of a lithographic structure according to an embodiment of the present disclosure; and

FIG. 12 is a schematic structural diagram illustrating a device for extracting a feature size of a lithographic structure according to an embodiment of the present disclosure.

### DETAILED DESCRIPTION

A method for extracting a feature size of a lithographic structure and related apparatus that are provided in the present disclosure may be applied to the field of semiconductors. The foregoing is merely an example and is not intended to limit the application fields of the method for extracting the feature size of the lithographic structure and related apparatus provided in the present disclosure.

In the specification, the claims and the drawings of the present disclosure, terms such as “first”, “second”, “third” and “fourth” are merely for distinguishing different objects rather than denoting any particular order.

In embodiments of the present disclosure, words “as an example” and “for example” are merely for describing an example, an illustration, or an explanation. Any embodiment or solution described as “as an example” or “for example” in the embodiments of the present disclosure shall not be interpreted as preferable or advantageous over other embodiments or solutions. Rather, the words such as “as an example” or “for example” are intended to present relevant concepts in a specific manner.

The terms in the embodiments of the present disclosure are only for the purpose of explaining specific embodiments of the present disclosure, rather than limiting the present disclosure.

In order to enable those skilled in the art to better understand the solutions of the present disclosure, the technical solutions of the embodiments of the present disclosure are described clearly and completely hereinafter with reference to the drawings of the embodiments of the present disclosure. Apparently, the embodiments are only part of the embodiments of the present disclosure, rather than all of the embodiments. Based on the embodiments of the present disclosure, all other embodiments obtained by those skilled in the art without any creative work fall into the protection scope of the present disclosure.

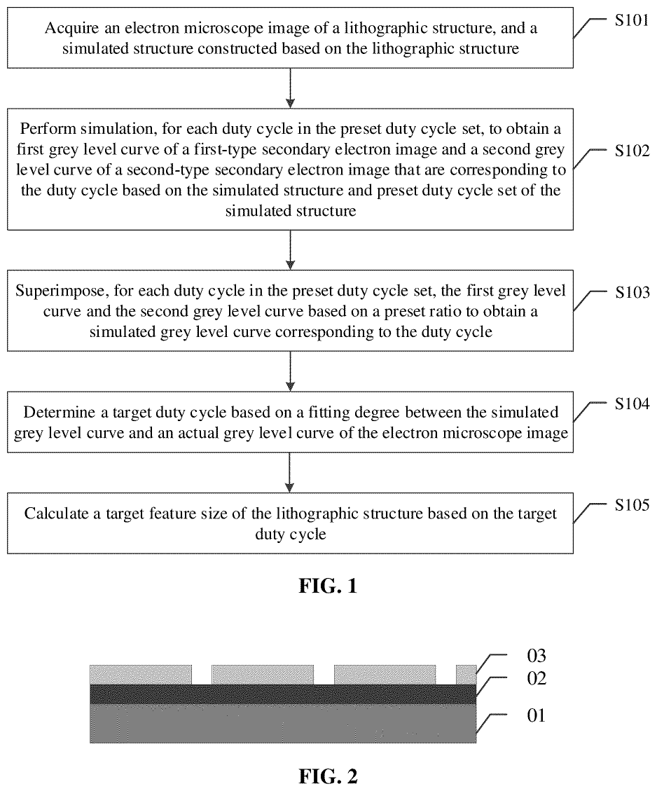

Reference is made to FIG. 1, which is a flowchart illustrating a method for extracting a feature size of a lithographic structure according to an embodiment of the present disclosure. The method includes steps S101 to S105.

In step S101, an electron microscope image of the lithographic structure and a simulated structure constructed based on the lithographic structure are acquired.

In the embodiment of the present disclosure, the lithographic structure is formed over a metal layer. As shown in FIG. 2, which is a schematic structural diagram illustrating a to-be-measured sample according to an embodiment of the present disclosure. The substrate 01, the metal layer 02, and the lithographic structure 03 are stacked sequentially. The metal layer may include, but is not limited to, films such as a gold layer, a silver layer, or a titanium layer, as well as films used in extreme ultraviolet lithography, such as a tantalum nitride (TaN) absorption layer, a ruthenium (Ru) capping layer, or a molybdenum/silicon (Mo/Si) multilayer reflective film.

As an example, based on structural parameters such as a pitch or a duty cycle of the lithographic structure, as well as structural parameters such as a material and thickness of each layer of a to-be-measured sample, a simulated structure of the to-be-measured sample is constructed. The electron microscope image may be an electron-beam image, a scanning electron microscope image, or other images capable of reflecting a structural feature such as a profile of the lithographic structure of the to-be-measured sample through grey level variations. In the embodiments of the present disclosure, the scanning electron microscope image, which is commonly used in the lithography field, is adopted as an example of the electron microscope image for illustration.

In step S102, based on the simulated structure and the preset duty cycle set of the simulated structure, for each duty cycle in the preset duty cycle set, simulation is performed to obtain a first grey level curve of a first-type secondary electron image and a second grey level curve of a second-type secondary electron image that are corresponding to the duty cycle.

In the embodiment, the first-type secondary electron refers to a secondary electron excited by an interaction between an incident electron beam and a surface of the lithographic structure, and the second-type secondary electron refers to a secondary electron generated by secondary excitation of a backscattered electron.

During a scanning process of the scanning electron microscope, the incident electron beam directly undergoes inelastic scattering with the atoms of the lithographic structure, transferring energy to valence electrons or weakly bound electrons, causing these electrons to escape from the sample surface. As a result, the first-type secondary electron with an energy lower than 50 eV is generated. Due to a shallow escape depth, morphology details of the lithographic structure, such as an edge profile of the line and a roughness are reflected in the first-type secondary electron image.

After elastic or inelastic collisions occur between the incident electron beam and atoms of the lithographic structure, a portion of electrons from the incident electron beam are scattered out of the surface of the lithographic structure at large angles greater than 90°, which are referred to as backscattered electrons. The backscattered electrons retain relatively high energy and have a deeper penetration depth. When escaping from the sample, the backscattered electrons undergoes inelastic collision with atoms along their path, exciting underlying material of the lithographic structure and transferring the energy to bound electrons within the sample. As a result, second-type secondary electrons with an energy lower than 50 eV are generated, leading to contrast reversal or edge blurring in the final electron microscopic image. The second-type secondary electron image is correlated with factors such as an atomic number of the material and the surface morphology.

The duty cycle is the ratio of a line width to a pitch of a periodic structure, which may be used to determine the feature size of the lithographic structure.

In the lithography process, due to the influences of process such as exposure and development, as well as intrinsic properties of the photoresist, the feature size of the developed lithographic structure generally exhibits a certain deviation from a designed size.

In view of this, a range of the duty cycle and a step size for the duty cycle may be predetermined based on a designed duty cycle to obtain a duty cycle set. Subsequently, by creating a program, simulated structures are constructed corresponding to different duty cycles in the duty cycle set, so as to facilitate extraction of the feature size of the lithographic structure by fitting the simulated structure to the actual lithographic structure. For example, the designed duty cycle is set to 0.5, and a duty cycle range of 0.35 to 0.6 and a step size of 0.01 are set based on the designed duty cycle, so as to obtain a duty cycle set expressed as [0.35, 0.36, 0.37, . . . , 0.59, 0.60].

The Monte Carlo simulation can accurately simulate the generation of secondary electrons in scanning electron microscope imaging and distinguish between first-type secondary electrons and second-type secondary electrons, so as to generate two types of simulated images and construct a high-precision, multi-parameter simulation image library including both the first-type secondary electron images and the second-type secondary electron images, which facilitates highly accurate extraction of a critical dimension.

After constructing simulated structures under different duty cycles through the created program, a method such as a Monte Carlo simulation may be performed to acquire, for each duty cycle, a first-type secondary electron image and a second-type secondary electron image. Further, grey level curves of the electron images corresponding to the duty cycles are calculated, such that a first grey level curve of the first-type secondary electron image and a second grey level curve of the second-type secondary electron image are obtained. The grey level curve shows the variation of the average grey level along the transverse direction of the image, with the edge information of the lithographic structure being reflected by this variation. The grey level curve is for extracting the feature size of the lithographic structure.

As an example, reference is made to FIG. 3, which is a schematic diagram illustrating simulated first-type secondary electron images respectively corresponding to different duty cycles according to an embodiment of the present disclosure. FIG. 3(a) corresponds to a duty cycle of 0.4, FIG. 3(b) corresponds to a duty cycle of 0.5, and FIG. 3(c) corresponds to a duty cycle of 0.6.

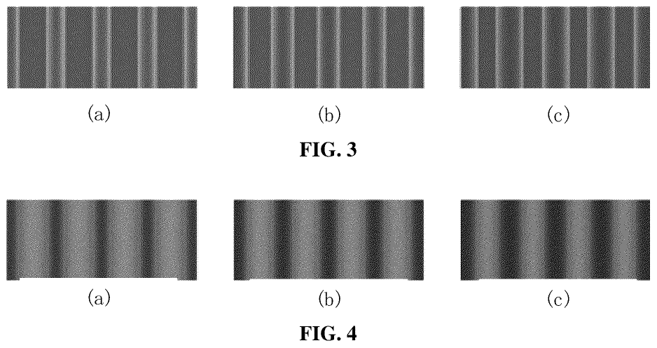

As an example, reference is made to FIG. 4, which is a schematic diagram illustrating simulated second-type secondary electron images respectively corresponding to different duty cycles according to an embodiment of the present disclosure. FIG. 4(a) corresponds to a duty cycle of 0.4, FIG. 4(b) corresponds to a duty cycle of 0.5, and FIG. 4(c) corresponds to a duty cycle of 0.6.

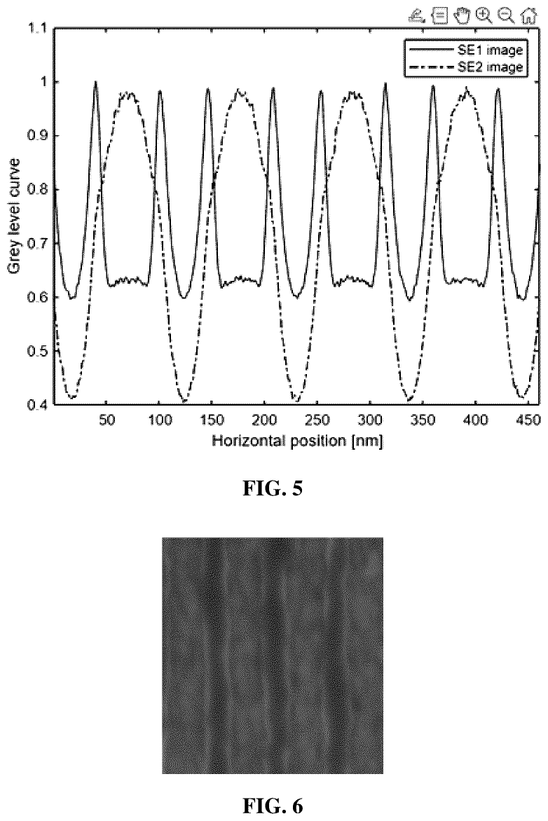

As an example, reference is made to FIG. 5, which is a schematic diagram illustrating a first grey level curve and a second grey level curve according to an embodiment of the present disclosure. An x-coordinate represents a horizontal position of a feature point on the grey level curve when the feature size is measured along the transverse direction of the image, and a y-coordinate represents a grey level value of the feature point. The first grey level curve (SE1 image), shown as a solid line, corresponds to the first-type secondary electron image at a duty cycle of 0.5 in FIG. 3(b). The second grey level curve (SE2 image), shown as a dash-Dotted line, corresponds to the second-type secondary electron image at a duty cycle of 0.5 in FIG. 4(b).

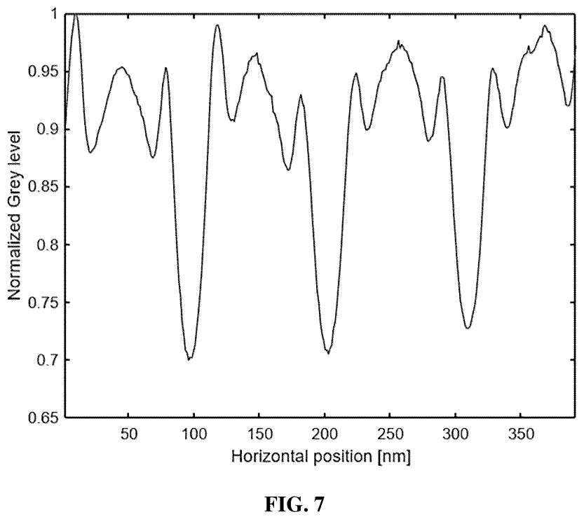

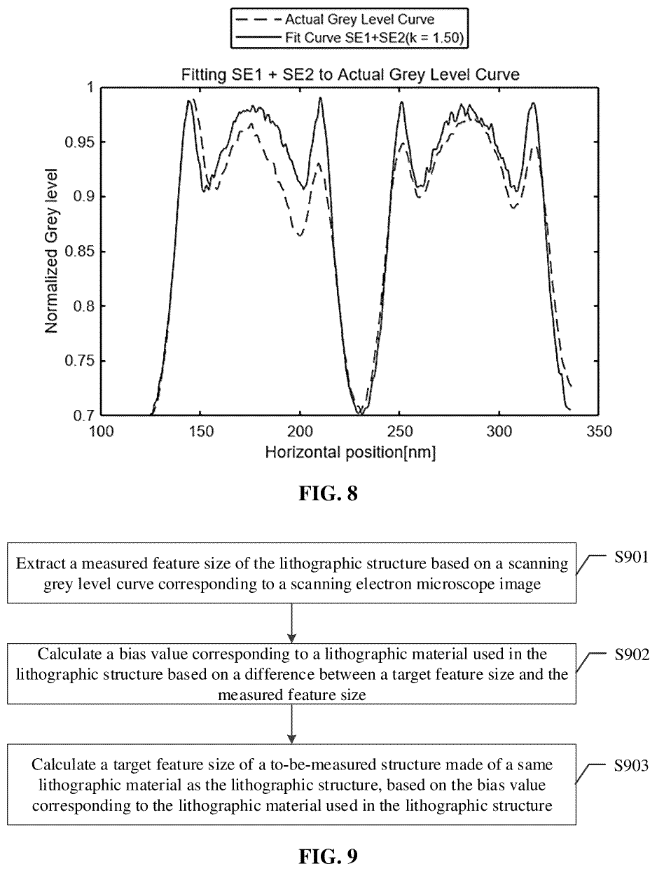

As an example, an actual grey level curve of a target region in the electron microscope image may be calculated at any time after acquiring the electron microscope image of the lithographic structure and before performing step S104. The electron microscope image of the target region is shown in FIG. 6, and the actual grey level curve corresponding to the target region is shown in FIG. 7, where the y-coordinates of the actual grey level curve shown in FIG. 7 represent normalized grey level values.

Since defects may exist in some portions of the actual lithographic structure and the quality of the electron microscope image may be affected by various factors, a region with relatively high image quality within the electron microscope image may be preselected as the target region. The target region includes at least one pitch of the lithographic structure. The number of the target region may be one or more. In the embodiments of the present disclosure, the case in which only one target region is present is described as an example. In the case where multiple target regions are present, steps S102 to S105 of the embodiment of the present disclosure may be performed for each target region among the multiple target regions to obtain multiple feature sizes corresponding to different positions of the lithographic structure.

After the actual grey level curve is acquired, interpolation may be performed on the actual grey level curve, so as to ensure that the number of data points on the actual grey level curve is consistent with the number of data points on the simulated grey level curve.

The data points refer to the average value of pixel grey levels along a scanning line direction, for example, in a direction perpendicular to the photoresist line. The physical meaning of the data point is a signal intensity of a secondary electron at each position when the electron beam scans the surface of the sample. Through the interpolation, the numbers of data points on the actual grey level curve, on the first grey level curve, and on the second grey level curve can be aligned, thereby facilitating the calculation of the fitting degree.

After obtaining the first-type secondary electron image and the second-type secondary electron image through simulation, a region in the first-type secondary electron image that corresponds to the target region may be selected, and the first grey level curve is calculated for the region. Similarly, a region in the second-type secondary electron image that corresponds to the target region may be selected, and the second grey level curve is calculated for the region.

In step S103, for each duty cycle in the preset duty cycle set, the first grey level curve and the second grey level curve are superimposed based on a preset ratio to obtain a simulated grey level curve corresponding to the duty cycle.

The actually acquired electron microscope image is a superposition of the first-type secondary electron image and the second-type secondary electron image, with a certain level of noise taken into account. An intensity of the first-type secondary electron image and an intensity of the second-type secondary electron image are related to the energy of the incident electron beam, the atomic number of the material of the sample, and the surface morphology of the sample. By performing fitting within a ratio range allowable by an intrinsic law, a superposition ratio of the first grey level curve and the second grey level curve is obtained. Further, fitting is performed between the simulated grey level curve after the superposition and the actual grey level curve of the electron microscope image to determine a target duty cycle.

In an embodiment, the normalized grey level values of the first grey level curve SE1 and the normalized grey level values of the second grey level curve SE2 are superimposed according to a pre-determined ratio. For example, the normalized grey level values of the first grey level curve and the normalized grey level values of the second grey level curve are superimposed in a ratio of 1:1.5 (k=1.50) to obtain the simulated grey level curve, as illustrated by the solid line in FIG. 8.

In step S104, a target duty cycle is determined based on a fitting degree between the simulated grey level curve and an actual grey level curve of the electron microscope image.

As an example, reference is made to FIG. 8, which is a schematic diagram illustrating grey level curve fitting effect according to an embodiment of the present disclosure. The solid line represents the simulated grey level curve obtained by superposing the first grey level curve SE1 and the second grey level curve SE2, and the dash-dotted line represents the actual grey level curve of the electron microscope image. Fitting is performed between the actual grey level curve and the simulated grey level curve, where a greater overlap between the two curves indicates a higher fitting degree. For example, the simulated grey level curve shown in FIG. 8 corresponds to a duty cycle of 0.43, and a fitting degree between the simulated grey level curve and the actual grey level curve is 0.97619.

For simulated grey level curves corresponding to different duty cycles, the fitting degree between each simulated grey level curve and the actual grey level curve is calculated. As a result, a target simulated grey level curve with a maximum fitting degree is determined, and a duty cycle corresponding to the target simulated grey level curve is determined as the target duty cycle.

In some embodiments, for each duty cycle in the preset duty cycle set, the first secondary electron image and the second secondary electron image may be superposed to obtain the simulated image corresponding to the duty cycle. Thereafter, the target duty cycle is determined based on the fitting degree between the simulated image and the electron microscope image.

In step S105, a target feature size of the lithographic structure is calculated based on the target duty cycle.

In some embodiments, the target feature size of the lithographic structure may be calculated through multiplying the target duty cycle by the designed pitch of the lithographic structure. For example, if the target duty cycle is 0.43 and the designed pitch of the lithographic structure is 100 nm, the resulting feature size of the lithographic structure is 43 nm.

Different lithographic structures typically have different designed pitches. The feature size of the lithographic structure is obtained by calculating the product of the target duty cycle and the designed pitch. For lithographic structures with different pitches, it is required to repeatedly perform steps S101 to S104 for simulation to obtain different target duty cycles respectively corresponding to lithographic structures with different pitches, thereby calculating feature sizes of lithographic structures with different pitches.

Accordingly, in the embodiment of the present disclosure, an image library for multiple duty cycles is constructed through simulation. A signal from the first-type secondary electrons reflecting the surface morphology and a signal from the second-type secondary electrons related to materials are combined to obtain a simulated grey level curve. Further, fitting is performed between the simulated grey level curve and the actual grey level curve to determine the target duty cycle, thereby obtaining the feature size of the lithographic structure through calculation. The method for extracting the feature size does not require direct measurement of the feature size of the lithographic structure based on the electron microscope image, and can effectively overcome high backscattering interference from the metal layer, thereby enabling more accurate extraction of the feature size of the lithographic structure formed over the metal layer.

For lithographic structures made of the same lithographic material, a deviation between the measured feature size extracted from the scanning grey level curve of the scanning electron microscope image and the target feature size calculated through steps S101 to S105 is generally constant.

In view of this, in some embodiments, after the target feature size of the lithographic structure is obtained through steps S101 to S105, a bias value between the measured feature size corresponding to the lithographic material used in the lithographic structure and the target feature size is determined based on the target feature size. For subsequently extracting the feature size of other to-be-measured structures made of the same lithographic material, the measured feature size of a to-be-measured structure that is obtained from the scanning grey level curve may be corrected with the bias value, thereby obtaining an accurate feature size of the to-be-measured structure.

In an embodiment, reference is made to FIG. 9, which is a flowchart illustrating a method for extracting a feature size of a to-be-measured structure based on bias value calibration according to an embodiment of the present disclosure. The method may include steps S901 to S903.

In step S901, a measured feature size of a lithographic structure is extracted based on a scanning grey level curve corresponding to a scanning electron microscope image.

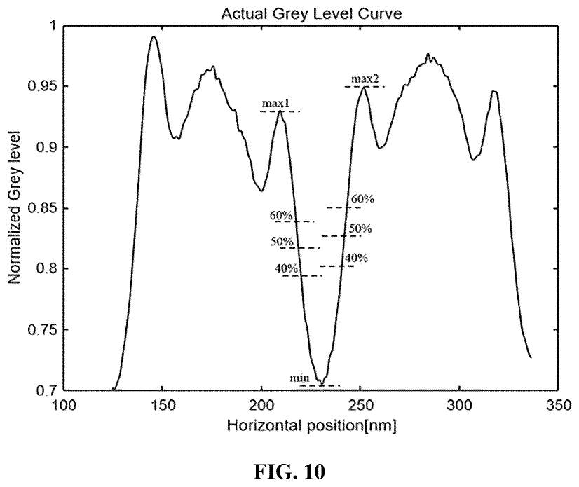

As an example, as shown in FIG. 10, x-coordinates of at least two preset grey level percentage points between a first peak point and a second peak point adjacent to the first peak point are determined, based on a y-coordinate max1 of the first peak point and a y-coordinate max2 of the second peak point, and a y-coordinate min of a valley point located between the first peak point and the second peak point on a scanning grey level curve (that is, the actual grey level curve) corresponding to a scanning electron microscope image. For example, the preset grey level percentage points may be defined as two sets of points whose y-coordinates are calculated as min+P×(max1−min) and min+P×(max2−min) respectively, where P is equal to 40%, 50%, 60% or the like, as illustrated in FIG. 10. Further, a difference between the x-coordinates of points which have a same grey level percentage and are located between the first peak point and the second peak point is calculated to extract the measured feature size d of the lithographic structure. As an example, through extensive experiments, a grey level percentage is selected from the at least two grey level percentages, and two points with the grey level percentage are determined as preset grey level percentage points, where x-coordinate difference between the two points approximates the target feature size most closely.

The grey level percentage point may be selected from a region of the scanning grey level curve in which the grey level value varies significantly, thereby facilitating obtaining a more accurate measured feature size.

In S902, a bias value corresponding to the lithographic material used in the lithographic structure is calculated based on a difference between the target feature size and the measured feature size.

Through steps S101 to S105, an accurate target feature size dᵣₑₐₗ of the lithographic structure is obtained through calculation. A difference between the target feature size dᵣₑₐₗ and the measured feature size d is calculated. Further, based on the equation dᵣₑₐₗ−d=2bias, the bias value corresponding to the lithographic material used in the lithographic structure is obtained.

In step S903, a target feature size of a to-be-measured structure made of the same lithographic material as the lithographic structure is calculated, based on the bias value corresponding to the lithographic material used in the lithographic structure.

In an embodiment, a scanning electron microscope image of a to-be-measured structure made of the same lithographic material as the lithographic structure is obtained first. Based on a scanning grey level curve of the scanning electron microscope image of the to-be-measured structure, a measured feature size of the to-be-measured structure is extracted based on the method described in step S901. The measured feature size of the to-be-measured structure is corrected based on the bias value corresponding to the lithographic material used in the lithographic structure, thereby obtaining an accurate target feature size of the to-be-measured structure.

Accordingly, for lithographic structures made of the same lithographic material, the deviation between the measured feature size and the target feature size calculated through steps S101 to S105 is generally constant. Based on this, the measured feature size of the to-be-measured structure is corrected through a pre-calibrated bias value to inversely derive the accurate target feature size of the to-be-measured structure. As a result, the accuracy of the extracted feature size is ensured and the feature size extraction process is simplified, thereby improving the efficiency of feature size extraction.

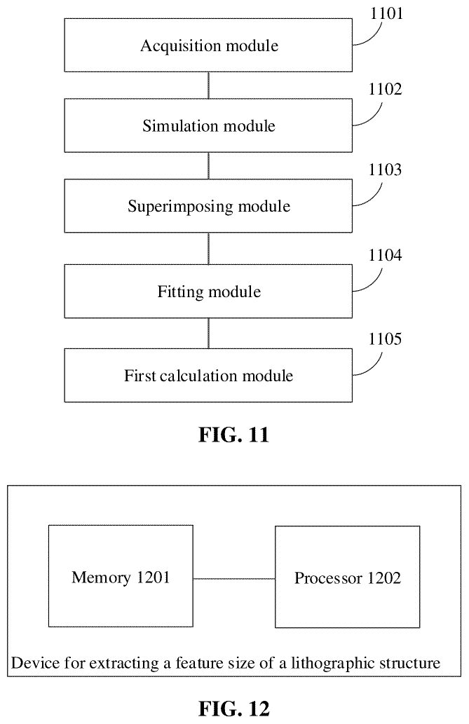

Reference is made to FIG. 11, which is a schematic diagram illustrating an apparatus for extracting a feature size of a lithographic structure according to an embodiment of the present disclosure. The apparatus includes: an acquisition module 1101, a simulation module 1102, a superimposing module 1103, a fitting module 1104, and a first calculation module 1105.

The acquisition module 1101 is configured to acquire an electron microscope image of the lithographic structure, and a simulated structure constructed based on the lithographic structure, where the lithographic structure is formed over a metal layer.

The simulation module 1102 is configured to perform simulation, for each duty cycle in a preset duty cycle set, to obtain a first grey level curve of a first-type secondary electron image and a second grey level curve of a second-type secondary electron image that are corresponding to the duty cycle based on the simulated structure and the preset duty cycle set of the simulated structure, where the first-type secondary electron refers to a secondary electron excited by an interaction between an incident electron beam and a surface of the lithographic structure, and the second-type secondary electron refers to a secondary electron generated by secondary excitation of a backscattered electron.

The superimposing module 1103 is configured to superimpose, for each duty cycle in the preset duty cycle set, the first grey level curve and the second grey level curve based on a preset ratio to obtain a simulated grey level curve corresponding to the duty cycle.

The fitting module 1104 is configured to determine a target duty cycle based on a fitting degree between the simulated grey level curve and an actual grey level curve of the electron microscope image.

The first calculation module 1105 is configured to calculate a target feature size of the lithographic structure based on the target duty cycle.

Accordingly, in the embodiment of the present disclosure, an image library for multiple duty cycles is constructed through simulation. A signal from the first-type secondary electrons reflecting the surface morphology and a signal from the second-type secondary electrons related to materials are combined to obtain a simulated grey level curve. Further, fitting is performed between the simulated grey level curve and the actual grey level curve to determine the target duty cycle, thereby obtaining the feature size of the lithographic structure through calculation. The method for extracting the feature size does not require direct measurement of the feature size of the lithographic structure based on the electron microscope image, and can effectively overcome high backscattering interference from the metal layer, thereby enabling more accurate extraction of the feature size of the lithographic structure formed over the metal layer.

In an embodiment, the apparatus for extracting the feature size of the lithographic structure further includes a second calculation module. The second calculation module includes a size extraction unit, a bias value calculation unit, and a size calculation unit. The size extraction unit is configured to extract a measured feature size of the lithographic structure based on a scanning grey level curve corresponding to the electron microscope image. The bias value calculation unit is configured to calculate a bias value corresponding to a lithographic material used in the lithographic structure based on a difference between the target feature size and the measured feature size. The size calculation unit is configured to calculate a target feature size of a to-be-measured structure made of a same lithographic material as the lithographic structure, based on the bias value corresponding to the lithographic material used in the lithographic structure.

In an embodiment, the size calculation unit is further configured to: determine x-coordinates of at least two preset grey level percentage points between a first peak point and a second peak point adjacent to the first peak point, based on y-coordinates of the first peak point and the second peak point, and a y-coordinate of a valley point between the first peak point and the second peak point on a scanning grey level curve corresponding to the electron microscope image; and extract the measured feature size of the lithographic structure based on a difference between x-coordinates of points having a same grey level percentage, where the points having the same grey level percentage are among the at least two preset grey level percentage points between the first peak point and the second peak point

In an embodiment, the size calculation unit is further configured to acquire an electron microscope image of a to-be-measured structure made of the same lithographic material as the lithographic structure; extract a measured feature size of the to-be-measured structure based on the electron microscope image of the to-be-measured structure; and correct the measured feature size of the to-be-measured structure based on the bias value corresponding to the lithographic material used in the lithographic structure to obtain a target feature size of the to-be-measured structure.

In an embodiment, the apparatus for extracting the feature size of the lithographic structure further includes a curve calculation module. The curve calculation module is configured to calculate an actual grey level curve of a target region in the electron microscope image, where the target region includes at least one pitch of the lithographic structure. The simulation module 1102 is further configured to perform simulation, for each duty cycle in the preset duty cycle set, to obtain a first grey level curve and a second grey level curve corresponding to the duty cycle based on the simulated structure and the preset duty cycle set of the simulated structure, where the first grey level curve is for a region of first-type secondary electron image that corresponds to the target region and the second grey level curve is for a region of the second-type secondary electron image that corresponds to the target region.

In an embodiment, the apparatus for extracting the feature size of the lithographic structure further includes an interpolation module. The interpolation module is configured to perform interpolation on the actual grey level curve, to cause the number of data points on the actual grey level curve to be consistent with the number of data points on the simulated grey level curve.

In an embodiment, the first calculation module 1105 is further configured to calculate the target feature size of the lithographic structure based on the target duty cycle and a designed pitch of the lithographic structure.

Reference is made to FIG. 12, which is a schematic structural diagram illustrating a device for extracting a feature size of a lithographic structure according to an embodiment of the present disclosure. The device includes a memory 1201 and a processor 1202.

The memory 1201 is configured to store program codes and transmit the program codes to the processor 1202.

The processor 1202 is configured to execute the method for extracting the feature size of the lithographic structure based on instructions in the program codes.

Moreover, a computer-readable storage medium is further provided according to an embodiment of the present disclosure. Computer instructions are stored in the computer-readable storage medium. When the computer instructions are executed by the device for extracting the feature size of the lithographic structure, the device for extracting the feature size of the lithographic structure performs the method for extracting the feature size of the lithographic structure.

It should be noted that the embodiments in this specification are described in a progressive manner, the same or similar parts among the embodiments may be referred to each other, and each of the embodiments emphasizes the differences from other embodiments. Particularly, since embodiments of the device and the storage medium are substantially similar to the embodiments of the method, the embodiments of the device and the storage medium are described briefly. For relevant parts, reference may be made to the description of the embodiments of the method. The embodiments related to the device and the storage medium described above are only exemplary, in which the units described as separate components may be or not be separated physically, components shown as units may be or not be physical units, that is, the components may be located at one place or distributed across multiple network units. Some or all of the modules may be selected according to an actual requirement to achieve the objective of the solution of the embodiments. Those skilled in the art can understand and implement the solution without any creative effort.

The above description is only a specific embodiment of the present disclosure, and the protection scope of the present disclosure is not limited thereto. Any changes or replacements that may be easily conceived by those skilled in the art within the technical scope disclosed in the present disclosure should fall within the protection scope of the present disclosure. Therefore, the protection scope of the present disclosure should be subject to the protection scope of the claims.

1. A method for extracting a feature size of a lithographic structure, comprising:
acquiring an electron microscope image of the lithographic structure, and a simulated structure constructed based on the lithographic structure, wherein the lithographic structure is formed over a metal layer;
performing simulation, for each duty cycle in a preset duty cycle set, to obtain a first grey level curve of a first-type secondary electron image and a second grey level curve of a second-type secondary electron image that are corresponding to the duty cycle based on the simulated structure and the preset duty cycle set of the simulated structure, wherein the first-type secondary electron refers to a secondary electron excited by an interaction between an incident electron beam and a surface of the lithographic structure, and the second-type secondary electron refers to a secondary electron generated by secondary excitation of a backscattered electron;
superimposing, for each duty cycle in the preset duty cycle set, the first grey level curve and the second grey level curve based on a preset ratio to obtain a simulated grey level curve corresponding to the duty cycle;
determining a target duty cycle based on a fitting degree between the simulated grey level curve and an actual grey level curve of the electron microscope image; and
calculating a target feature size of the lithographic structure based on the target duty cycle.

2. The method according to claim 1, wherein after the calculating a target feature size of the lithographic structure based on the target duty cycle, the method further comprises:
extracting a measured feature size of the lithographic structure based on a scanning grey level curve corresponding to the electron microscope image;
calculating a bias value corresponding to a lithographic material used in the lithographic structure based on a difference between the target feature size and the measured feature size; and
calculating a target feature size of a to-be-measured structure made of a same lithographic material as the lithographic structure, based on the bias value corresponding to the lithographic material used in the lithographic structure.

3. The method according to claim 2, wherein the extracting a measured feature size of the lithographic structure based on a scanning grey level curve corresponding to the electron microscope image comprises:
determining x-coordinates of at least two preset grey level percentage points between a first peak point and a second peak point adjacent to the first peak point, based on y-coordinates of the first peak point and the second peak point, and a y-coordinate of a valley point between the first peak point and the second peak point on a scanning grey level curve corresponding to the electron microscope image; and
extracting the measured feature size of the lithographic structure based on a difference between x-coordinates of points having a same grey level percentage, where the points having the same grey level percentage are among the at least two preset grey level percentage points between the first peak point and the second peak point.

4. The method according to claim 2, wherein the calculating a target feature size of a to-be-measured structure made of a same lithographic material as the lithographic structure, based on the bias value corresponding to the lithographic material used in the lithographic structure comprises:
acquiring an electron microscope image of a to-be-measured structure made of the same lithographic material as the lithographic structure;
extracting a measured feature size of the to-be-measured structure based on the electron microscope image of the to-be-measured structure; and
correcting the measured feature size of the to-be-measured structure based on the bias value corresponding to the lithographic material used in the lithographic structure to obtain the target feature size of the to-be-measured structure.

5. The method according to claim 1, wherein after the acquiring an electron microscope image of the lithographic structure, the method further comprises:
calculating an actual grey level curve of a target region in the electron microscope image, wherein the target region comprises at least one pitch of the lithographic structure, and wherein
the performing simulation, for each duty cycle in a preset duty cycle set, to obtain a first grey level curve of a first-type secondary electron image and a second grey level curve of a second-type secondary electron image that are corresponding to the duty cycle based on the simulated structure and the preset duty cycle set of the simulated structure comprises:
performing simulation, for each duty cycle in the preset duty cycle set, to obtain a first grey level curve and a second grey level curve corresponding to the duty cycle based on the simulated structure and the preset duty cycle set of the simulated structure, wherein the first grey level curve is for a region of first-type secondary electron image that corresponds to the target region and the second grey level curve is for a region of the second-type secondary electron image that corresponds to the target region.

6. The method according to claim 5, wherein after the calculating an actual grey level curve of a target region in the electron microscope image, the method further comprises:
performing interpolation on the actual grey level curve, to cause the number of data points on the actual grey level curve to be consistent with the number of data points on the simulated grey level curve.

7. The method according to claim 1, wherein the calculating a target feature size of the lithographic structure based on the target duty cycle comprises:
calculating the target feature size of the lithographic structure based on the target duty cycle and a designed pitch of the lithographic structure.

8. An apparatus for extracting a feature size of a lithographic structure, comprising:
an acquisition module,
a simulation module,
a superimposing module,
a fitting module, and
a first calculation module, wherein
the acquisition module is configured to acquire an electron microscope image of the lithographic structure, and a simulated structure constructed based on the lithographic structure, wherein the lithographic structure is formed over a metal layer;
the simulation module is configured to perform simulation, for each duty cycle in a preset duty cycle set, to obtain a first grey level curve of a first-type secondary electron image and a second grey level curve of a second-type secondary electron image that are corresponding to the duty cycle based on the simulated structure and the preset duty cycle set of the simulated structure, wherein the first-type secondary electron refers to a secondary electron excited by an interaction between an incident electron beam and a surface of the lithographic structure, and the second-type secondary electron refers to a secondary electron generated by secondary excitation of a backscattered electron;
the superimposing module is configured to superimpose, for each duty cycle in the preset duty cycle set, the first grey level curve and the second grey level curve based on a preset ratio to obtain a simulated grey level curve corresponding to the duty cycle;
the fitting module is configured to determine a target duty cycle based on a fitting degree between the simulated grey level curve and an actual grey level curve of the electron microscope image; and
the first calculation module is configured to calculate a target feature size of the lithographic structure based on the target duty cycle.

9. A device for extracting a feature size of a lithographic structure, comprising:
a memory, and
a processor, wherein
the memory is configured to store program codes and transmit the program codes to the processor; and
the processor is configured to, based on the program codes, execute the method for extracting the feature size of the lithographic structure according to claim 1.

10. A non-transitory computer-readable storage medium, wherein computer programs are stored in the non-transitory computer-readable storage medium, and when the computer programs are executed by a device for extracting a feature size of a lithographic structure, the device performs the method for extracting the feature size of the lithographic structure according to claim 1.
